(19) United States
(12) Patent Application Publication
(10) Pub. No.: US 2015/0054523 A1
(43) Pub. Date: Feb. 26, 2015

(54) DEVICES AND TECHNIQUES FOR DETECTING FAULTS IN PHOTOVOLTAIC SYSTEMS

(71) Applicant: Fraunhofer USA, Inc., Plymouth, MI (US)

(72) Inventor: James R. Perkinson, Medford, MA (US)

(73) Assignee: Fraunhofer USA, Inc., Plymouth, MI (US)

(21) Appl. No.: 14/469,334

(22) Filed: Aug. 26, 2014

Related U.S. Application Data
(60) Provisional application No. 61/869,887, filed on Aug. 26, 2013.

(51) Int. Cl. G01R 31/02; G01R 31/26

(52) U.S. Cl. CPC G01R 31/025; G01R 31/2605
USPC 324/510

(57) ABSTRACT

Devices and techniques for detecting faults (e.g., ground faults) in photovoltaic (PV) systems are provided. A fault-detection impedance component may be included in a PV system on the path to equipment ground. The PV system may determine whether a ground fault exists based, at least in part, on a measured impedance between a conductor of the PV system and a ground node of the PV system, and on a reference impedance. When it is determined that a ground fault exists in the PV system, action may be taken to mitigate the ground fault.

### CROSS-REFERENCE TO RELATED APPLICATIONS

This application claims the benefit under 35 U.S.C. §119(e) of U.S. Provisional Application Ser. No. 61/869,887, titled “Devices and Techniques for Detecting Faults in Photovoltaic Systems” and filed Aug. 26, 2013 under Attorney Docket No. F0690.70005US00, which application is hereby incorporated herein by reference in its entirety.

### STATEMENT REGARDING FEDERALLY SPONSORED RESEARCH OR DEVELOPMENT

This invention was made with government support under Grant Nos. DE-EE0006035.000 and DE-EE0006035-005 awarded by the Department of Energy. The government has certain rights in this invention.

### BACKGROUND

1. Field

The present application relates to devices and techniques for detecting faults (e.g., ground faults) in photovoltaic systems.

2. Related Art

Photovoltaic systems convert photonic energy (e.g., sunlight) into electricity. Undetected faults in photovoltaic systems may lead to safety hazards, such as fires.

### SUMMARY

According to an aspect of the present application, a method of determining whether a fault exists in a photovoltaic system is provided, the method comprising: determining whether a ground fault exists based, at least in part, on a measured impedance between a conductor of the photovoltaic system and a ground node of the photovoltaic system, and on a reference impedance; and when it is determined that a ground fault exists in the photovoltaic system, mitigating the ground fault.

According to an aspect of the present application, a device configured to couple one or more photovoltaic cells to an inverter is provided, the device comprising: a terminal configured to couple one or more photovoltaic cells to an inverter via a conductor, the conductor being coupled to a ground node by a fuse circuit; and a fault-detection impedance component coupled to the conductor in series with the fuse circuit.

According to an aspect of the present application, a photovoltaic system is provided, comprising: an inverter; one or more photovoltaic cells coupled to the inverter via a conductor, the conductor being coupled to a ground node by a fuse circuit; and a fault-detection impedance component coupled to the conductor in series with the fuse circuit.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 illustrates a perspective view of a photovoltaic module (“PV module”), according to some techniques;

FIG. 2 illustrates voltage-current (V-I) curves of PV modules and voltage-power curves of PV modules, according to some techniques;

FIG. 3 illustrates a schematic of a photovoltaic string (“PV string”), according to some techniques;

FIG. 4 illustrates a schematic of multiple PV strings being combined in a “combiner box,” according to some techniques;

FIG. 5 illustrates a DC section 500 of a photovoltaic system, from PV modules to inverter 501, according to some techniques;

FIG. 6 illustrates a schematic of an electrical representation 600 of a grounded photovoltaic system, according to some techniques;

FIG. 7 illustrates a schematic of an electrical representation 700 of a grounded photovoltaic system exhibiting a first fault, according to some techniques;

FIG. 8 illustrates a schematic of an electrical representation 800 of a portion of a grounded photovoltaic system exhibiting a first fault, with other portions of the schematic removed for clarity, according to some techniques;

FIG. 9 illustrates a schematic of an electrical representation 900 of a portion of a photovoltaic system exhibiting a first fault, the PV system including a path from a grounded conductor to a ground impedance with a fault-detection impedance component inserted in the path, according to some embodiments;

FIG. 10 illustrates a block diagram of a photovoltaic (PV) system with a fault-detection impedance component, according to some embodiments;

FIG. 11 illustrates a block diagram of a PV system controller 1006, according to some embodiments;

FIG. 12 illustrates a flowchart of a fault-mitigation technique, according to some embodiments; and

FIG. 13 illustrates a block diagram of a computing device on which aspects of the present disclosure may be implemented, according to some embodiments.

### DETAILED DESCRIPTION

Today there is significant concern surrounding the safety of ‘Grounded’ PV systems. In North America, PV systems may be constructed in either ‘Grounded’ or ‘Floating’ configurations. ‘Grounded’ PV systems are the vast majority of installations, and some conventional ‘Grounded’ PV systems suffer from a well-documented failure mode that is currently not being sufficiently addressed by typical safety equipment. This failure mode can cause a fire, damaging structures and placing firefighters and other personnel at risk. Some embodiments described in this application provide a low cost technique which eliminates this failure mode (e.g., by detecting and mitigating the fault that leads to this failure mode).

### Anatomy of a PV System

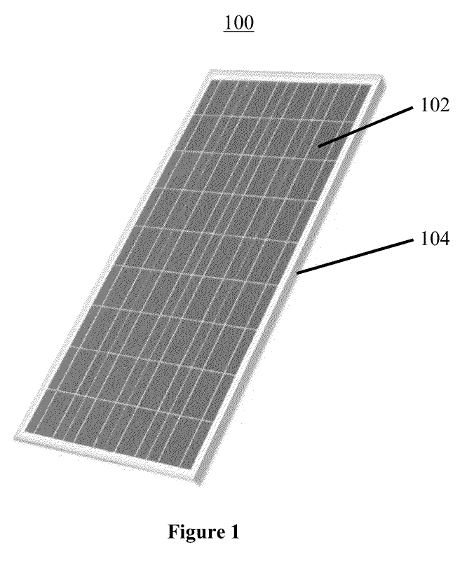

FIG. 1 illustrates a “PV module” 100, which may be used to convert solar radiation into DC electricity. As shown in FIG. 1, a PV module may include solar cells 102, which may be connected together internally and encased in a glass and metal frame structure 104. The frame 104 of a PV module 100 may be metal and may be connected to an equipment ground. On the backside of PV module 100, there may be two wire connectors for the positive and negative conductors, respectively, of the internal PV solar cells 102.

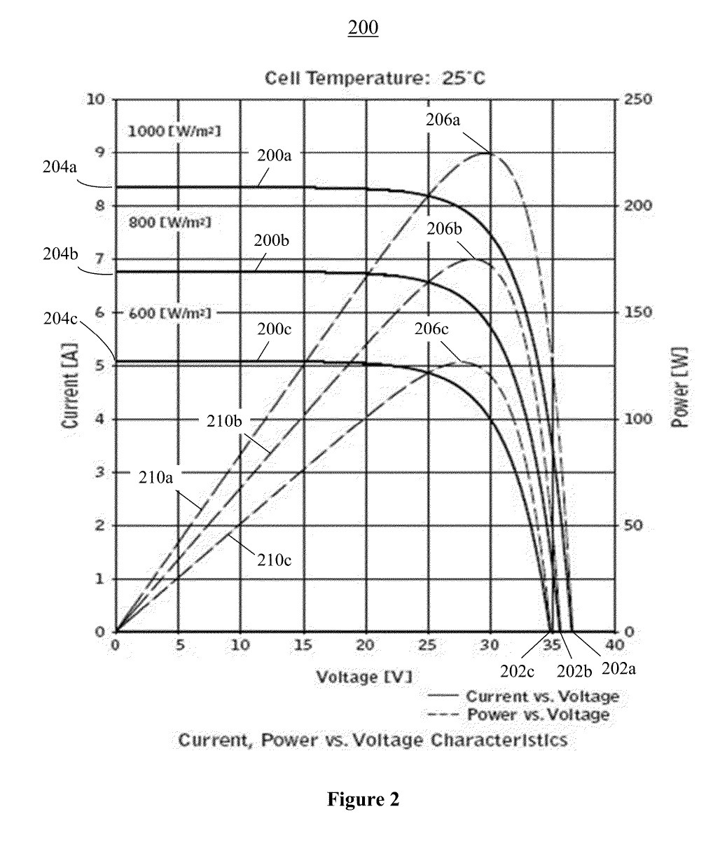

A PV module 100 may be characterized by a voltage-current (V-I) curve, as shown in FIG. 2, which illustrates three V-I curves 200a-200c and indicates for each V-I curve: (1) open circuit (no load) DC voltage 202a-202c, and (2) short circuit (full load) DC current 204a-204c. A PV module 100 may be characterized by a voltage-power (V-P) curve, as shown in FIG. 2, which illustrates three V-P curves 210a-210c, and indicates for each curve a maximum power point 206a-206c (the voltage V and power I where maximum power is produced under Standard Temperature and Pressure conditions (STP)).

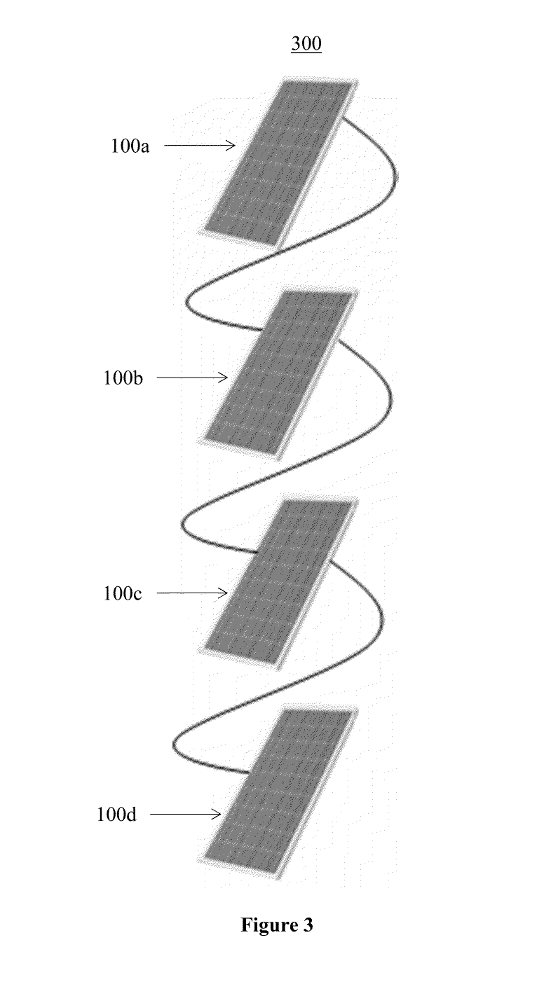

The positive and negative conductors of a set of PV modules may be connected in series to form “PV strings” 300, as illustrated in FIG. 3. The V-I curve of a PV string 300 may be obtained by adding the voltages of the individual PV modules included in the PV string. In some cases, a PV string may be sized for a cumulative open circuit voltage of either 600V or 1000V, depending on jurisdiction.

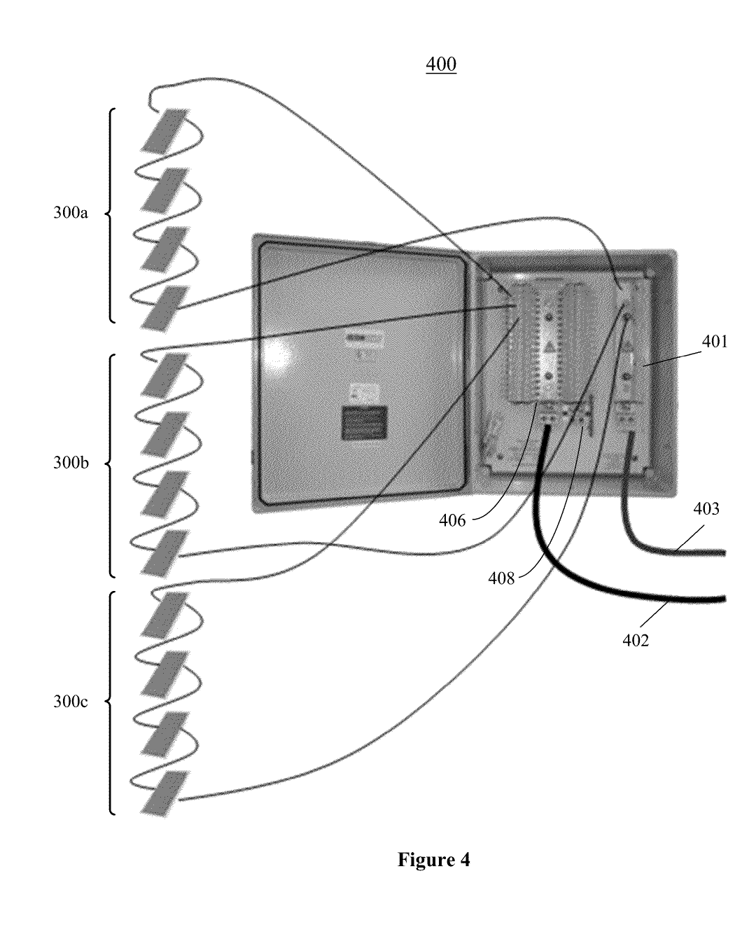

For increased power, PV strings 300 may be combined in parallel (adding the currents) in one or more “combiner boxes” 401, as illustrated in FIG. 4. A combiner box may accept multiple strings (both positive and negative conductors) and combine them into a pair of large gauge conductors (known as “home runs”) (402, 403). In some installations, the home runs may connect to an inverter. In some installations (e.g., large installations), the home runs may be aggregated in a “recombiner box”, which accepts multiple home runs (both positive and negative conductors) and combines them into a pair or large gauge conductors. A combiner box may include a series fuse 406 on one (or both) of the individual conductors corresponding to a PV string. In some installations (e.g., small installations), the function of a combiner box may be integrated into an inverter 501. In some installations (e.g., in typical installations over 10 kW), combiner boxes may be integrated into the racking structure on which the PV modules are disposed. A combiner box may carry provisions for an equipment ground conductor 408, which may collect the conductors that ground the PV module frames and/or racking, allowing for an equipment ground conductor to be brought back to an inverter or other ground reference point. The combiner box may include metal structural components, which may be connected to the equipment ground.

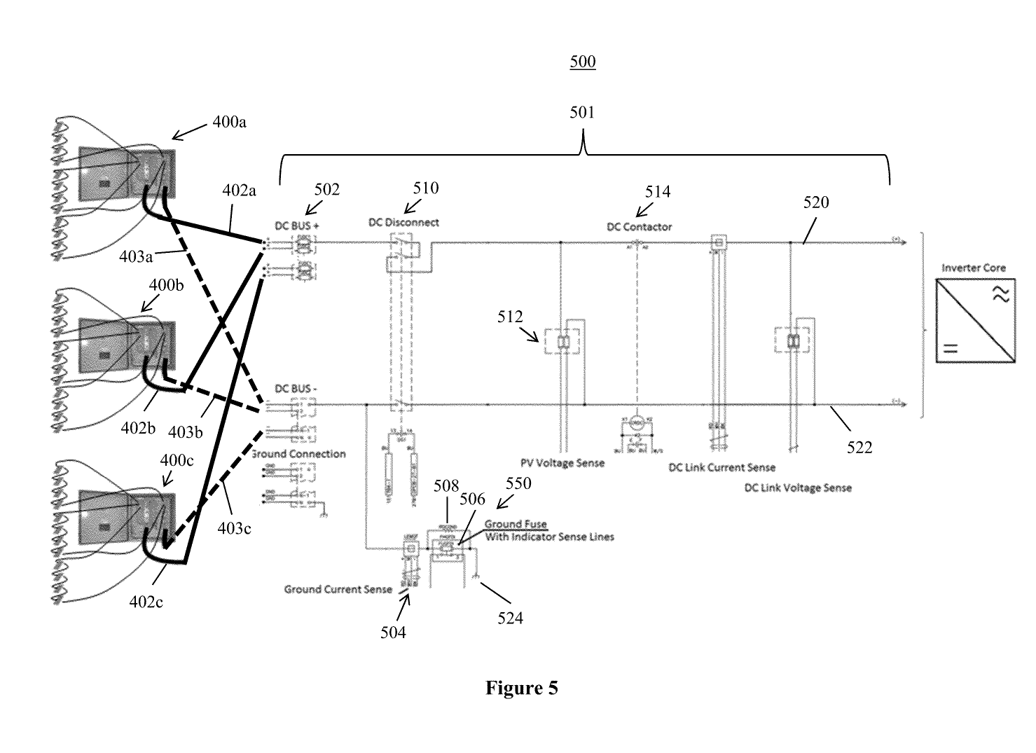

FIG. 5 illustrates a DC section 500 of a photovoltaic system, from PV modules to inverter 501, according to some techniques. As can be seen in FIG. 5, the home runs may be brought to an inverter for aggregation. At the inverter 501, the entire PV power system may be provided with a reference to ground. In some systems, the negative conductors 403 are provided the ground reference, and become known as the ‘grounded conductors’ throughout the system. In that case the positive conductors 402 become known as the ‘ungrounded conductors’ and the system is said to be ‘negatively grounded’. It is also possible to have the reverse, which is commonly known as a ‘positively grounded’ PV system. A third alternative is a ‘floating system’, where no ground reference is provided, such that both conductors are ungrounded.

In the system illustrated in FIG. 5, the positive home runs 402 are combined together on the ungrounded PV conductor 520 through respective DC fuses 502, and the negative home runs 403 are combined together on the grounded PV conductor 522. The grounded PV conductor 522 of the system of FIG. 5 may be connected to system ground 524 through a fault-detection component 550 configured to break the circuit if the current exceeds a threshold value. In some implementations, fault-detection component 550 may include a circuit breaker. In some implementations, fault-detection component 550 may include a ground-fault detector and interrupter (GFDI). In some implementations, fault-detection component 550 may include a current sensing transducer 504 and a ground fuse 506, which may be an ‘indicator type’ fuse. Resistive component 508 may be placed around (e.g., in parallel with) the ground fuse 506 to provide an impedance reference (e.g., a high impedance reference) when the ground fuse 506 is not in service. Any suitable resistive component 508 may be used, including, without limitation, a resistor having an impedance greater than 1 kΩ, greater than 5 kΩ, greater than 10 kΩ, greater than 50 kΩ, or greater than 100 kΩ.

PV conductors 520 and 522 may be coupled to the inverter's core through manual DC disconnect 510, a user-actuated contactor which, when actuated, interrupts both un-grounded and grounded conductors. Voltage sense circuit 512 and DC contactor 514 may be configured to actuate the ungrounded conductor 520 under computer control (e.g., without actuating the grounded conductor 522).

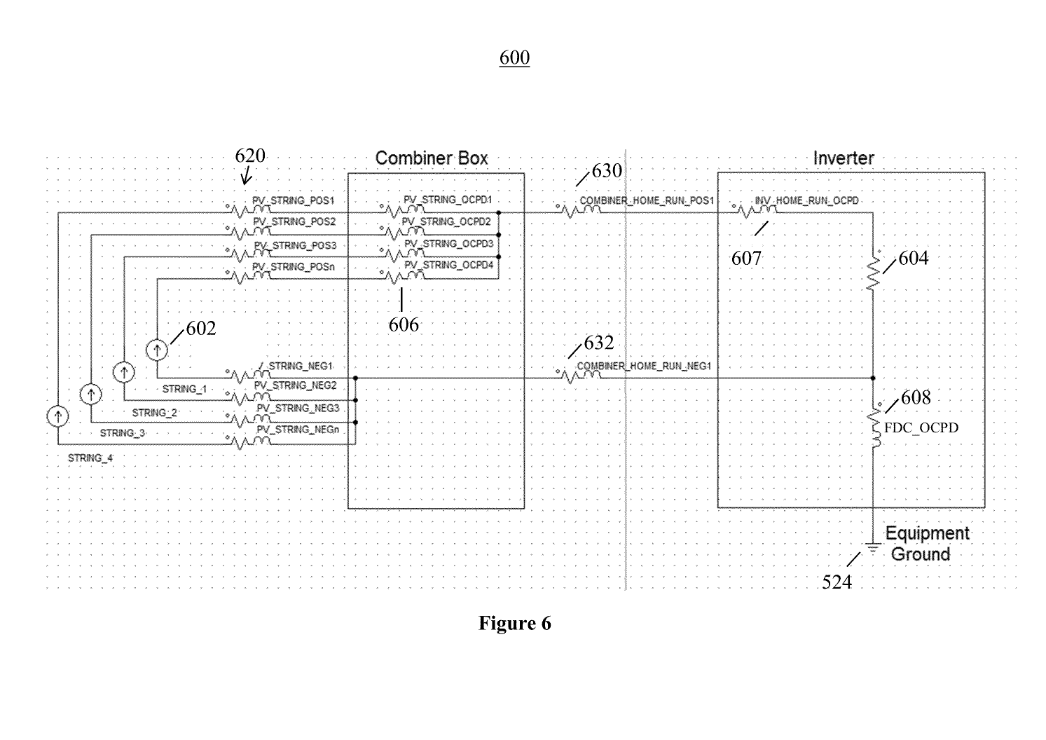

FIG. 6 illustrates a schematic of an electrical representation 600 of a grounded photovoltaic system, according to some techniques. As can be seen in FIG. 6, an electrical representation of a grounded PV system may include complex impedances. In the example of FIG. 6, fusing, cables, components, and devices are represented with example values, which are non-limiting. Each “PV string” is represented as a current source 602, and the back end of inverter 501 is represented as a bulk resistor 604 for simplicity. PV string cables are represented as respective impedances 620. The positive and negative home run cables are represented as impedances 630 and 632, respectively. Combiner box fuses 406, DC fuses 502, and fault-detection component 550 are represented as over current protection devices (“OCPDs”) 606, 607, and 608, respectively. The electrical schematics of FIGS. 6-9 will be used to illustrate the blind spot, and how some embodiments allow detection of the blind spot. The PV system represented by FIG. 6 has a single combiner box with 4 strings; however the analysis is valid for both larger and smaller systems.

### Code and Standards Background

According to NEC 690.5, “Grounded DC photovoltaic arrays shall be provided with DC ground fault protection meeting the requirements of 690.5 (A) through (C) to reduce fire hazards”. In some systems, compliance with the code is accomplished by inserting a fault-detection component 550 between the system's grounded PV conductor and equipment ground. In some implementations, the fault-detection component 550 may include a ground fault detector and interrupter (GFDI). Sections 690.5 (A) through (C) describe the system interruption and isolation requirements during a detected fault. In addition, UL 1741 Section 31 requires specific detection thresholds for the GFDI, varying by system AC capacity. These thresholds may range, for example, from 1 A for small systems up to 5 A for utility scale systems, and refer to the detected level of ground current which shall trigger a fault. Under these guidelines, manufacturers may use an ‘indicator fuse’ in series with a current detector to comply with the code. The indicator fuse may be rated for a specific current threshold per UL 1741, and the current transducer may be software programmed to trip at the same current limit, or the fuse indicator, registering a fault. The rest of system then shuts down, and disconnects the array of PV modules from the inverter.

It has been widely publicized that a known ‘blind spot’ to the above-described method of fault detection and interruption is a dual fault condition. The first fault in the dual fault condition occurs when there is an accidental connection between a ‘grounded conductor’ per NEC 690 and actual ground. This first fault may not induce enough current to be detected by the fault-detection component 550, and therefore may remain undetected. The second fault in the dual fault conditions occurs when there is a connection between an ‘ungrounded conductor’ and ground, which opens the ground fuse and shuts the system down, as intended. However, after the second fault, the grounded conductor associated with the first fault may conduct the full system current with limited interruption capabilities, potentially resulting in fires.

Due to the high profile nature of these faults, Solar ABCs was engaged to study this problem and work with national labs and industry to determine a course of resolution. The final report (“Inverter Ground-Fault Detection ‘Blind Spot’ and Mitigation Methods,” Solar America Board for Codes and Standards), published in 2013, mentions seven methods of mitigating this blind spot. None of the proposed methods fully address detecting the problem directly and without great expense.

### Proposed Solution

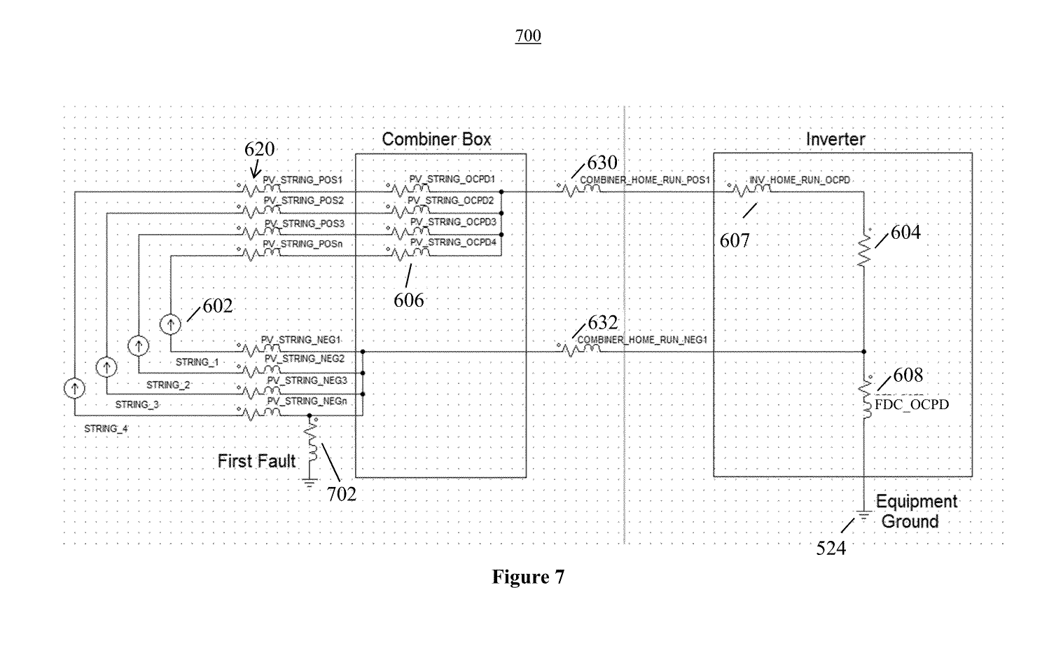

FIG. 7 illustrates a schematic of an electrical representation 700 of a grounded photovoltaic system exhibiting a first fault 702, according to some techniques. First fault 702 could occur at a PV module, in the cabling of a PV string, at a combiner box, at a recombiner box, in the home run cables, or in any other part of a grounded PV system where a connection might be made between a grounded conductor and another electrical node (e.g., a grounded electrical node, such as equipment ground). In the example of FIG. 7, the ground current created by first fault 702 (shown at the combiner box) is not sufficient to trigger fault-detection component 550.

The circuit of FIG. 7 can be examined further by looking at illustrative values. Table 1 contains examples of resistance and inductance values in an electrical representation of a photovoltaic system, according to some techniques. For the Solar ABCs study, the resistance values in the third column of Table 1 were used (from typical construction assumptions). The Solar ABCs work only evaluated real resistance. In the last column, illustrative inductance values are shown. For this analysis, the impedance of the first fault 702 (the impedance of the path connecting the grounded conductor to actual ground) is assumed to be 25Ω, which is considered high impedance and more difficult to detect than a low-impedance fault, such as an electrical short.

TABLE 1

| SolarABC | | Resistance | | |
|---|---|---|---|---|
| Reference | Component Name | (Ohms) | Inductance | |
| R_{GFPD} | Ground Fuse | 0.252 | 15 | nH |
| R_{ECG} | Earth Ground | 0.041 | 0.032 | mH |
| R_{PVString} | PV String Resistance | 0.25 | 0.029 | mH |
| R_{Comb} | Combiner Home Run | 0.001265 | 0.028 | mH |
| R_{OCPD} | Combiner String Fuse | 0.077 | 15 | nH |
| | Combiner Home Run Fuse | 0.02 | 15 | nH |

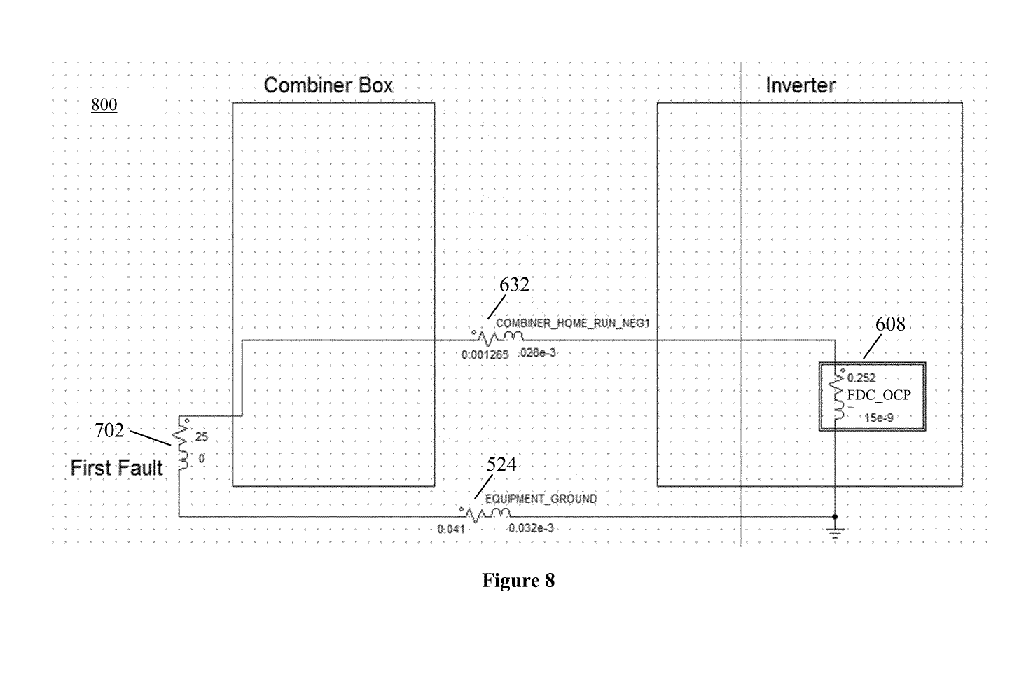

FIG. 8 illustrates a schematic of an electrical representation 800 of a portion of a grounded photovoltaic system exhibiting a first fault 702, with other portions of the schematic removed for clarity. As can be seen in FIG. 8, when observing from the inverter, the first fault 702 would be viewed as simple impedance in parallel with the OCPD 608 representing fault-detection component (e.g., GFDI) 550 as shown in FIG. 8. First fault 702 is represented as a 25Ω real resistance with negligible imaginary impedance. (The resistance and inductance values shown in FIG. 8 correspond to the values listed in Table 1 and are shown by way of example only. These values are non-limiting.)

At low (DC) frequencies, it may be very difficult to detect a ground path parallel to fault-detection component 550 (represented by OPCD 608) in the system of FIG. 8. In the above example, the series combination of the resistances of first fault 702, negative home run conductor 632, and equipment grounding path 524 is several orders of magnitude greater than the resistance R_{FDC} of fault-detection component 550 (represented by OPCD 608). The net result is resistance equivalent to the resistance R_{FDC} of fault-detection component 550. Looking at the complex resistance in parallel:

$${R}_{grounded conductor to ground ( no fault )} = {R}_{FDC} = 0.252 \\ {R}_{grounded conductor to ground ( fault )} = {R}_{FDC} \text{//} ( {R}_{Combiner Home Run} + {R}_{Equipment Ground} + {R}_{fault} ) = 0.252 \text{//} ( 0.001265 + 0.041 + 25 ) = ) .252 // 25.042265$$

$${R}_{grounded conductor to ground ( fault )} = \frac{1}{\frac{1}{0.252} + \frac{1}{25.042265}} = .249489$$

This represents a vector length of 0.249 compared to the original 0.252, which is a decrease of only 1.1%.

At higher frequencies, it may be difficult to detect a ground path parallel to fault-detection component 550 (represented by OPCD 608), as the fault may be masked by the relatively large imaginary impedance of the conductor cables, with comparison to the small imaginary impedance of the fault-detection component. With f=100 khz, ω=6.28 e⁵:

$${Z}_{grounded conductor to ground ( no fault )} = {Z}_{FDC} = 0.252 + j ω 15 {e}^{- 9} = 0.252 + j 9.42 {e}^{- 3}$$

$${Z}_{grounded conductor to ground ( fault )} = {Z}_{FDC} \text{//} ( {Z}_{Combiner Home Run} + {Z}_{Equipment Ground} + {Z}_{fault} ) = 0.252 + j ω 15 {e}^{- 9} \text{//} ( 0.001265 + jω 0.028 {e}^{- 3} + 0.041 + jω 0.032 {e}^{- 3} + 25 ) = 0.252 + j 9.42 {e}^{- 3} \text{//} ( 0.001265 + j17 .59 + 0.041 + j20 .10 + 25 ) = 0.252 + j9 .42 {e}^{- 3} \text{//} 25.042265 + j37 .69$$

$${Z}_{grounded conductor to ground ( fault )} = \frac{1}{\frac{1}{0.252 + j9 .4 {e}^{- 3}} + \frac{1}{25.042265 + j37 .69}} = .2511 + j0 .0105$$

This represents a vector length of 0.251 compared to the original 0.252, which is a decrease of only 0.3%

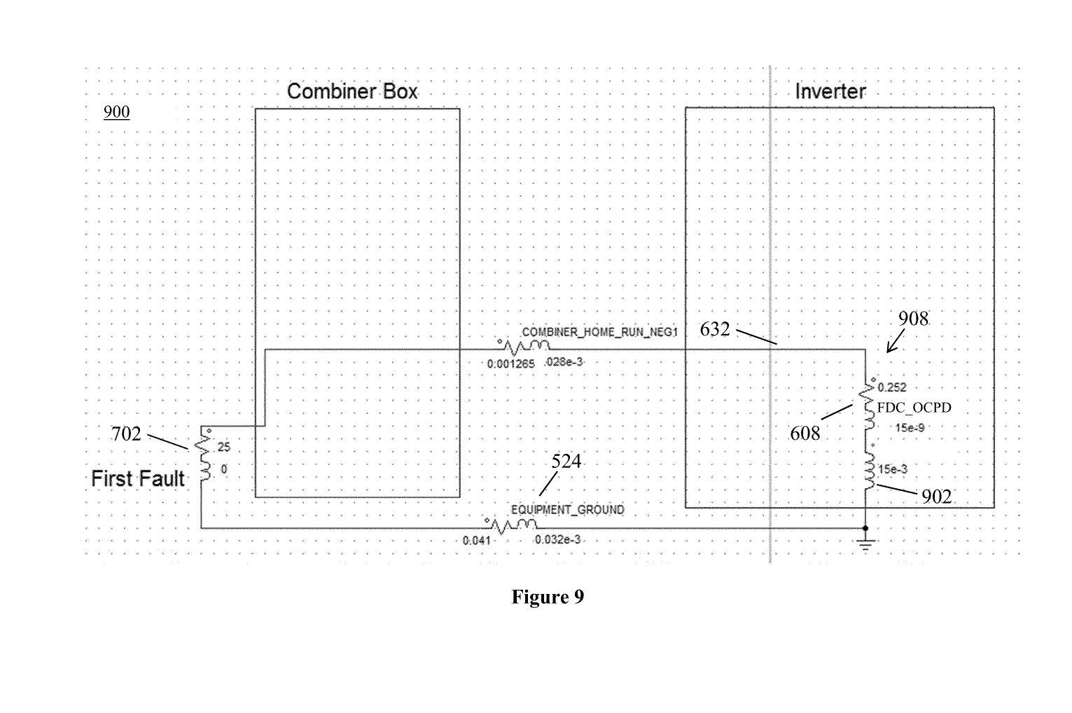

In some embodiments, detection of ground faults is facilitated by adding a fault-detection impedance component 902 to a ground fuse path (a path to equipment ground that passes through fault-detection component 550). FIG. 9 illustrates a schematic of an electrical representation 900 of a portion of a photovoltaic system exhibiting a first fault 702, according to some embodiments. In the embodiment illustrated in FIG. 9, a fault-detection impedance component (FDIC) 902 has been inserted in the ground fuse path. With fault-detection impedance component 902 added to the ground fuse path, as shown in FIG. 9, upon measuring the impedance between the ‘grounded conductor’ 632 and ground (e.g., equipment ground 524), an additional ground path (e.g., a ground fault) may be more easily detected.

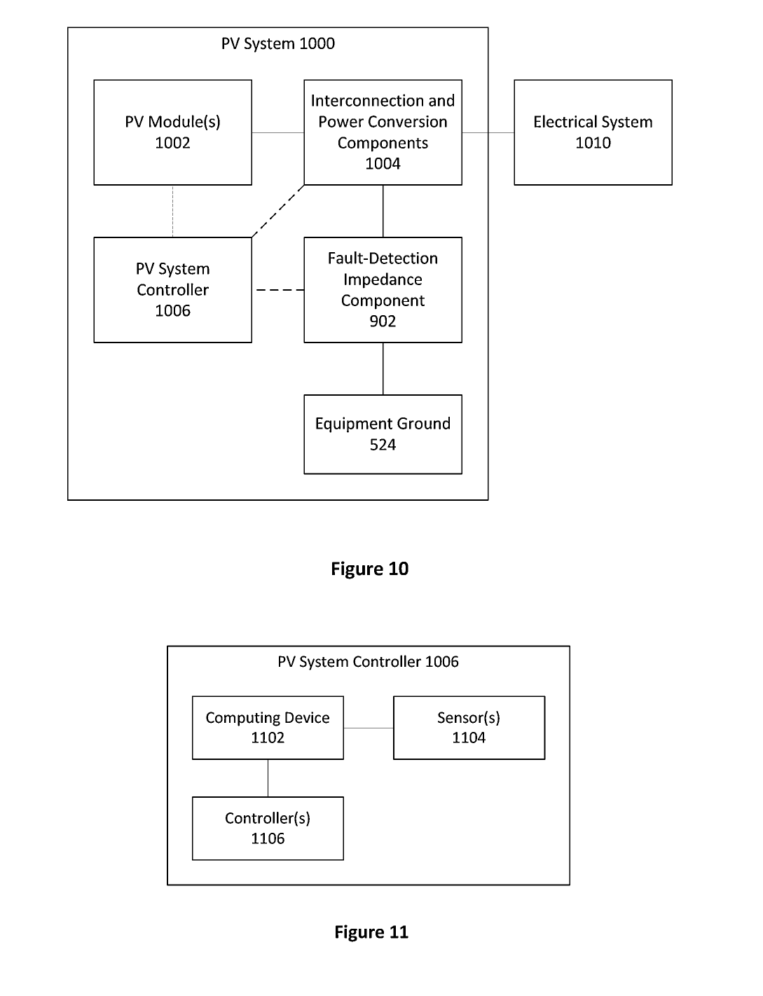

FIG. 10 illustrates a photovoltaic (PV) system 1000 with a fault-detection impedance component 902, according to some embodiments. PV system 1000 may be configured to provide power to an electrical system 1010. As can be seen in FIG. 10, PV system 1000 may include one or more PV modules 1002, a set of interconnection and power conversion components 1004 (e.g., cables, combiner box(es), recombiner box(es), fuse(s), disconnects, contactors, inverter(s), etc.), a fault-detection impedance component 902, an equipment ground 524, and a PV system controller 1006. The PV module(s) 1002 and the interconnection and power conversion components may be electrically coupled to equipment ground 524 via a ground fuse path through fault-detection impedance component 902. Fault-detection impedance component 902 may be configured to facilitate detection of the above-described “first fault” condition. PV system controller 1006 may be configured to monitor and/or control the operation of PV system 1000. PV system controller 1006 may be coupled (e.g., communicatively, electrically, and/or mechanically coupled) to one or more components of PV system 1000, including, without limitation, the PV module(s) 1002, various interconnection and power conversion components 1004, and/or fault-detection impedance component 902.

Fault-detection impedance component 902 may be implemented using any suitable technique. In some embodiments, fault-detection impedance component 902 may be implemented using one or more cores (e.g., ferrite cores, ferromagnetic cores, air cores, and/or any other suitable cores) attached to a conductor on the ground fuse path. A core may be installed by clamping the core onto a conductor and/or winding the core around a conductor. Using one or more cores to implement fault-detection impedance component 902 may facilitate retrofit applications, in which the fault-detection component 902 is added to a pre-existing PV system 1000. In some cases, such cores may be allowed by existing codes and standards, as they may have no effect on the operation of other fault-detection components 550 (e.g., a GFDI circuit).

In some embodiments, fault-detection impedance component 902 may be implemented using one or more inductors inserted on the ground fuse path. In some embodiments, fault-detection inductors may saturate at low current levels. In some embodiments, fault-detection inductor cores may be formed from ferrite. In some embodiments, fault-detection inductor cores may be formed from materials other than ferrite, including, without limitation, steel, silicon steel, air, and/or soft iron powder. The use of non-ferrite cores may yield inductors with smaller cores while still providing the necessary functionality for first fault detection.

The impedance of fault-detection impedance component 902 may include a resistive portion and/or a reactive portion. In some embodiments, the impedance of fault-detection impedance component 902 may be fully resistive (real-valued). In some embodiments, the impedance of fault-detection impedance component 902 may be fully reactive (imaginary-valued). In some embodiments, the impedance of fault-detection impedance component 902 may be partially resistive and partially reactive (complex-valued).

The resistive portion of the impedance of fault-detection impedance component 902 may have any suitable value. In some embodiments, the value of the resistive portion may be between 0 and 50 ohms, between 0 and 30 ohms, between 5 and 30 ohms, between 10 and 30 ohms, between 5 and 25 ohms, between 10 and 25 ohms, or 25 ohms. The reactive portion of the impedance of fault-detection component 902 may have any suitable value. In some embodiments, the value of the reactive portion may be between 0 and 20 kilo-ohms for a specified frequency. In some embodiments, detection of a ground fault may be facilitated if the resistive portion, the reactive portion, and/or the total magnitude of the impedance of fault-detection impedance component 902 has a value greater than (e.g., 100 times greater than, 10 times greater than, or slightly greater than), approximately equal to, or at least half as large as the value of, respectively, the resistance, the reactance, and/or the total magnitude of the impedance of the ground fault.

Choosing the impedance value of fault-detection impedance component 902 may involve a tradeoff between energy efficiency and fault-detection sensitivity. As the impedance value of fault-detection impedance component 902 increases, the power dissipation of the PV system's ground fuse path may increase, thereby decreasing the PV system's overall power efficiency. On the other hand, as the impedance value of fault-detection impedance component 902 decreases, it may become more difficult for the system to detect high-impedance ground faults. In some embodiments, the impact of fault-detection impedance component 902 on the PV system's power efficiency may be reduced by placing a switched, low-impedance path in parallel with fault-detection impedance component 902, such that fault-detection impedance component 902 is bypassed (e.g., effectively shorted out) when the switch is closed. The PV system may open the switch when measurements relating to ground-fault detection are made, and close the switch at other times, such that the power efficiency of the PV system decreases only when fault-detection impedance component 902 is actually being used to detect faults.

FIG. 11 illustrates a block diagram of a PV system controller 1006, according to some embodiments. PV system controller 1006 may be configured to monitor and/or control the operation of PV system 1000. In some embodiments, PV system controller 1006 may include a computing device 1102, one or more sensors 1104, and one or more controllers 1106. In some embodiments, the sensor(s) 1104 may be configured to monitor various signals in PV system 1000, including, without limitation, the voltages, currents, and/or impedances at PV modules, PV strings, combiner boxes, recombiner boxes, and/or other suitable locations in PV system 1000. PV system controller 1006 may monitor voltages and/or currents within PV system 1000 using any suitable monitoring and/or measuring techniques.

In some embodiments, computing device 1102 may control the measurement of signal values through the sensor(s) 1104. For example, computing device 1102 may determine when to measure a signal value, and may generate control signals to operate the corresponding sensor(s) 1104. In some embodiments, some signal values may be measured periodically, intermittently, or at any suitable (e.g., scheduled) times. In some embodiments, some signal values may be measured in response to detection of conditions that trigger the corresponding measurement.

In some embodiments, the controller(s) 1106 may be configured to control various aspects of the operation of PV system 1000, including, without limitation, activation of the PV modules, deactivation of the PV modules, activation of the inverter, deactivation of the inverter, connection of the PV modules to the inverter, disconnection of the PV modules from the inverter, connection of the PV system to electrical system 1010, and/or disconnection of the PV system from electrical system 1010. In some embodiments, one or more of the controller(s) 1106 may be integrated into other components of PV system 1000, including, without limitation, the PV modules, PV strings, combiner boxes, and/or recombiner boxes.

In some embodiments, computing device 1102 may control the operation of PV system 1000 through the controller(s) 1106. For example, computing device 1102 may determine when to activate/deactivate or connect/disconnect various components of PV system 1000, and may generate control signals to operate the corresponding controller(s) 1106. In some embodiments, the determination to activate/deactivate or connect/disconnect a component may be based on the measurements obtained by sensor(s) 1104, data derived from the measurements obtained by sensor(s) 1104, and/or any other suitable data.

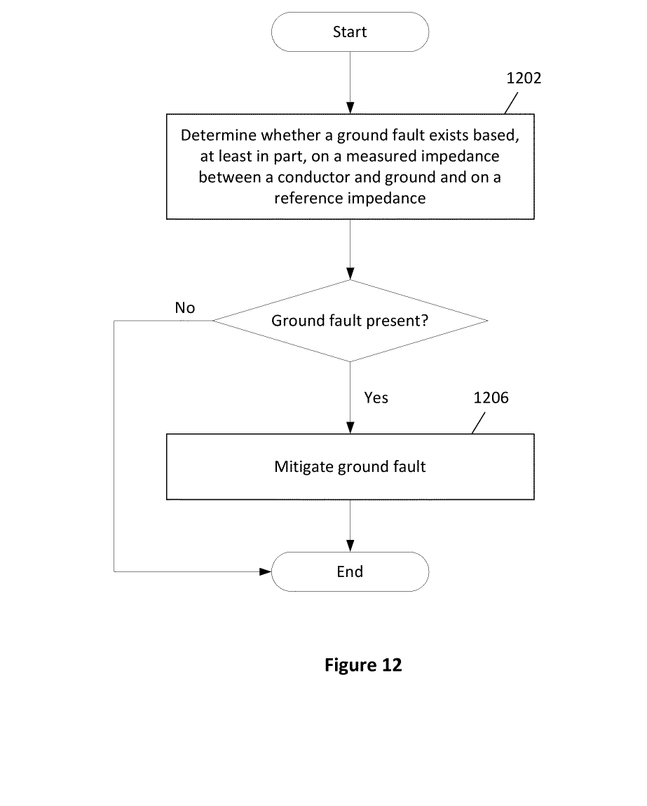

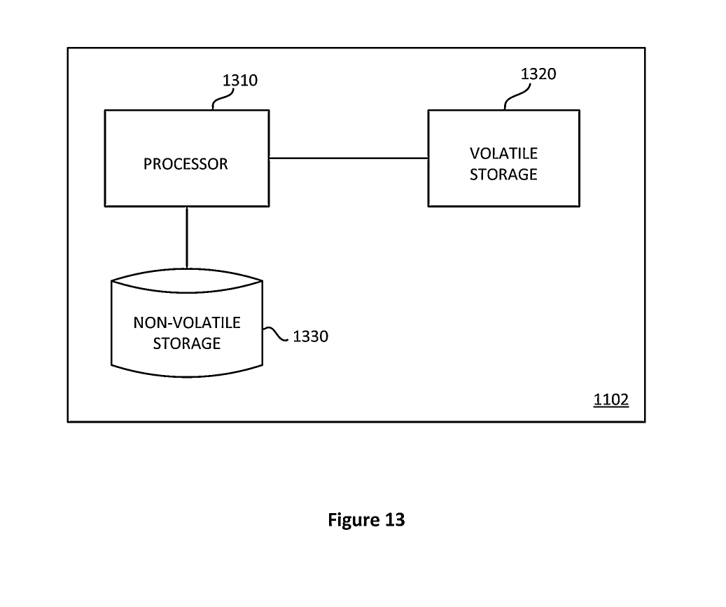

In some embodiments, PV system controller 1006 may be configured to perform a fault-mitigation method. FIG. 12 illustrates a fault-mitigation method 1200, according to some embodiments. At step 1202 of fault-mitigation method 1200, it is determined whether a ground fault exists in a PV system based on a measured impedance between a conductor and ground and on a reference impedance. The reference impedance may comprise an expected impedance between the conductor and ground (e.g., a minimum expected impedance between the conductor and ground when a ground fault is not present). The reference impedance may be the same for two or more (e.g., all) conductors, or may differ for different conductors. In some embodiments, the reference impedance for a conductor may comprise the nominal impedance of fault-detection impedance component 902. In some embodiments, the reference impedance for a conductor may comprise the nominal impedances of one or more (e.g., all) components on a path between the conductor and ground (e.g., on the lowest-impedance path between the conductor and ground when a ground fault is not present). In some embodiments, the reference impedance for all conductors may be the impedance of fault-detection impedance component 902. In some embodiments, the ground potential used to determine the reference impedance may be equipment ground 524.

In some embodiments, the reference impedance may be determined based on a schematic or other representation of the PV system 1000. In some embodiments, the reference impedance may be determined by measuring an impedance (e.g., the impedance between the conductor and ground, the impedance of fault-detection impedance component 902, and/or the impedance of any other suitable component of PV system 1000). In some embodiments, such measurements may be obtained when there is no ground fault present in PV system 1000.

In some embodiments, multiple reference impedances may be determined for a same conductor. In some embodiments, reference impedances may be determined for different signal frequencies for a same conductor. For example, reference impedances may be determined for a D.C. signal and/or for one or more A.C. signals (e.g., A.C. signals having frequencies greater than or equal to 60 Hz, 120 Hz, 1 kHz, and/or 10 kHz).

The measured impedance between the conductor and ground may comprise the total impedance between the conductor and ground, or a portion of the impedance between the conductor and ground. The measured impedance between the conductor and ground may be determined using any suitable technique. In some embodiments, PV system controller 1006 may use one or more sensors 1104 to measure the impedance between the conductor and ground. In some embodiments, the measured impedance between the conductor and ground may be determined by applying a voltage V at a suitable location in PV system 1000 (e.g., between the conductor and ground), measuring a current I at a suitable location in PV system 1000 (e.g., through the ground fuse path), and calculating the measured impedance Z as the ratio of the applied voltage V to the measured current I. In some embodiments, the measured impedance between the conductor and ground may be determined by inserting a voltage source V at a suitable location in PV system 1000 (e.g., in the ground fuse path), measuring the current I at a suitable location in PV system 1000 (e.g., through the voltage source, or through the ground fuse path), and calculating the measured impedance Z as the ratio of the voltage source V to the measured current I. In some embodiments, the measured impedance between a conductor and ground may be determined by applying a current I at a suitable location in PV system 1000, measuring the voltage V at a suitable location in PV system 1000, and calculating the measured impedance Z as the ratio of the measured voltage V to the applied current I. In some embodiments, two or more impedances between the conductor and ground may be measured (e.g., two or more impedances corresponding to two or more respective signal frequencies, including, without limitation, signal frequencies greater than or equal to 60 Hz, 120 Hz, 1 kHz, and/or 10 kHz).

The existence of a ground fault may be determined by comparing the measured impedance between the conductor and ground to the corresponding reference impedance (e.g., the reference impedance corresponding to the same conductor and the same frequency as the measured impedance). In some embodiments, it may be determined that a ground fault is present if the measured impedance is less than the corresponding reference impedance. In some embodiments, it may be determined that a ground fault is present if the measured impedance is less than 95%, less than 90%, less than 80%, less than 70%, less than 60%, less than 50%, less than 40%, less than 30%, or less than 25% of the corresponding reference impedance. As the ratio of measured impedance to reference impedance decreases, the probability of an actual ground fault rather than a spurious measurement may increase, but the system's ability to detect high-impedance ground faults may decrease.

An example of ground fault detection is now described, with reference to FIG. 9. In some embodiments, detection of ground conductor faults is performed using a device that uses an A.C. voltage source (e.g., a voltage source with a frequency of at least 10 kHz), thereby taking advantage of a the reactance of fault-detection impedance component 902 inserted in the primary ground fault path 908.

In this example, 15 mH is inserted in the ground path:

$${Z}_{grounded conductor to ground ( no fault )} = {Z}_{FDC\_OCPD} + {Z}_{Ferrite\_inductor} = 0.252 + jω 15 {e}^{- 3} = 0.252 + j 9.42 {e}^{3}$$

$${Z}_{grounded conductor to ground ( fault )} = {Z}_{FDC\_OCPD} + {Z}_{Ferrite\_inductor} \text{//} ( {Z}_{Combiner Home Run} + {Z}_{Equipment Ground} + {Z}_{fault} ) == 0.252 + j9 .42 {e}^{3} \text{//} ( 0.001265 + j ω0 .028 {e}^{- 3} + 0.041 + j ω0 .032 {e}^{- 3} + 25 ) = 0.252 + j9 .42 {e}^{3} \text{//} ( 0.001265 + j17 .59 + 0.041 + j20 .10 + 25 ) = 0.252 + j9 .42 {e}^{3} \text{//} 25.042265 + j37 .69$$

$${Z}_{grounded conductor to ground ( fault )} = \frac{1}{\frac{1}{0.252 + j9 .4 {e}^{3}} + \frac{1}{25.042265 + j37 .69}} = 24.84 + j37 .60$$

In this example, the vector magnitude of the impedance between the conductor and ground is 45.06 ohms when the ground fault is present, compared to 9,420 ohms when the ground fault is not present, which is a decrease of 99%. This example clearly illustrates how adding a fault-detection impedance component 902 to a PV system can have a big impact when trying to detect faults located deep in the array. (The resistance and inductance values shown in FIG. 9 correspond to the values listed in Table 1 and are shown by way of example only. These values are non-limiting.)

In response to determining that a ground fault is present, action may be taken to mitigate the ground fault at step 1206 of method 1200. In some embodiments, the mitigating action may comprise deactivating PV system 1000 and/or deactivating portions of PV system 1000. In some embodiments, the mitigating action may comprise disconnecting PV system 1000 from electrical system 1010 and/or disconnecting portions of PV system 1000 from each other. In some embodiments, the deactivation or disconnection of the PV system 1000 or portions thereof may be controlled by PV system controller 1006 through one or more controllers 1106. In some embodiments, the mitigating action may comprise providing an alert regarding the presence of the ground fault. An alert may be provided using any suitable technique, including, without limitation, displaying a suitable message (e.g., on a display device controlled by or associated with PV system 1000), producing a suitable sound (e.g., an alarm-type noise, such as the noises produced by smoke alarms), sending an electronic message (e.g., email, text message, or voicemail) to a designated recipient (e.g., a fire department, an owner of the PV system, and/or a resident of a structure powered by the PV system).

In some embodiments, method 1200 may be repeated for a plurality of frequencies for a same conductor, such that the impedance between the conductor and ground is measured for a plurality of frequencies (e.g., the D.C. impedance and/or one or more A.C. impedances between the conductor and ground may be measured). In some embodiments, method 1200 may be repeated for a plurality of conductors (e.g., ‘grounded’ conductors, ‘ungrounded’ conductors, positive conductors, and/or negative conductors). In some embodiments, action may be taken to mitigate a ground fault if it is determined that a ground fault between any conductor and ground is present.

In some embodiments, method 1200 may be performed periodically, intermittently, in response to instructions received by PV system controller 1006, in response to detecting certain conditions in PV system 1006, and/or at any other suitable time.

An illustrative implementation of a computing device 1102 that may be used in connection with some embodiments of the present invention is shown in FIG. 7. One or more computing devices such as computing device 700 may be used to implement method 1200. The computing device 1102 may include one or more processors 1310, one or more computer-readable storage media (i.e., tangible, non-transitory computer-readable media), e.g., volatile storage 1320, and/or one or more non-volatile storage media 1330, which may be formed of any suitable non-volatile data storage media. The processor 1310 may control writing data to and reading data from the volatile storage 1320 and/or the non-volatile storage device 1330 in any suitable manner, as aspects of the present invention are not limited in this respect. To perform method 1200, processor 1310 may execute one or more instructions stored in one or more computer-readable storage media (e.g., volatile storage 1320), which may serve as tangible, non-transitory computer-readable media storing instructions for execution by processor 1310. In some embodiments, one or more processors 1310 may include one or more processing circuits, including, but not limited to, a central processing unit (CPU), a microcontroller, an embedded controller, a graphics processing unit (GPU), a field-programmable gate array (FPGA), an accelerator, an application-specific integrated circuit (ASIC), and/or any other suitable device (e.g., circuit) configured to process data.

It should be appreciated from the foregoing that one embodiment of the invention is directed to a method 1200 having applicability to detection of ground faults in photovoltaic systems. Method 1200 may be performed, for example, by one or more components of a computing device 1102, although other implementations are possible, as method 1200 is not limited in this respect.

Method 1200 may be implemented in any of numerous ways. For example, some embodiments of method 1200 may be implemented using hardware, software or a combination thereof. When implemented in software, the software code can be executed on any suitable processor (e.g., processing circuit) or collection of processors, whether provided in a single computer or distributed among multiple computers. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

In this respect, it should be appreciated that one implementation of embodiments of the present invention comprises at least one computer-readable storage medium (i.e., at least one tangible, non-transitory computer-readable medium, e.g., a computer memory, a floppy disk, a compact disk, a magnetic tape, or other tangible, non-transitory computer-readable medium) encoded with a computer program (i.e., a plurality of instructions), which, when executed on one or more processors, performs above-discussed steps of embodiments of method 1200. The computer-readable storage medium can be transportable such that the program stored thereon can be loaded onto any computing device to implement aspects of the present invention discussed herein. In addition, it should be appreciated that the reference to a computer program which, when executed, performs above-discussed functions, is not limited to an application program running on a host computer. Rather, the term “computer program” is used herein in a generic sense to reference any type of computer code (e.g., software or microcode) that can be used to program one or more processors to implement above-discussed aspects of the present invention.

Some embodiments have been described in which a reference impedance is compared to a measured impedance. In some embodiments, the magnitude of the reference impedance may be compared to the magnitude of the measured impedance. In some embodiments, the magnitude of the resistive portion or the reactivate portion of the reference impedance may be compared to the magnitude of the resistive portion or the reactive portion, respectively, of the measured impedance. In some embodiments, the phase of the reference impedance may be compared to the phase of the measured impedance. In some embodiments, a detection circuit may be configured to measure the current of an isolated A.C. voltage source (e.g., an A.C. voltage source with a frequency of at least 10 kHz), or may be configured to use active phase shift information to detect circuit impedance changes.

Some embodiments have been described in which the PV modules of a PV system are connected to a single DC/AC inverter, but the invention is not limited in this regard. In some embodiments, the fault-detection techniques described herein may be applied to PV systems in which one or more DC/AC micro-inverters are used to convert DC power to AC power at or near the PV modules.

The phraseology and terminology used herein is for the purpose of description and should not be regarded as limiting. The use of “including,” “comprising,” “having,” “containing,” “involving,” and variations thereof, is meant to encompass the items listed thereafter and additional items. Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Having described several embodiments of the invention in detail, various modifications and improvements will readily occur to those skilled in the art. Such modifications and improvements are intended to be within the spirit and scope of the invention. Accordingly, the foregoing description is by way of example only, and is not intended as limiting. The invention is limited only as defined by the following claims and the equivalents thereto.

What is claimed is:

1. A method of determining whether a fault exists in a photovoltaic system, the method comprising:
determining whether a ground fault exists based, at least in part, on a measured impedance between a conductor of the photovoltaic system and a ground node of the photovoltaic system, and on a reference impedance; and
when it is determined that a ground fault exists in the photovoltaic system, mitigating the ground fault.

2. The method of claim 1, wherein determining whether the ground fault exists comprises comparing the measured impedance to the reference impedance.

3. The method of claim 1, wherein determining whether the ground fault exists comprises determining whether the measured impedance is less than the reference impedance or less than a specified percentage of the reference impedance.

4. The method of claim 1, wherein the reference impedance depends on an impedance along a path between the conductor and the ground node, and wherein the path includes a ground fuse.

5. The method of claim 4, wherein the path further includes a fault-detection impedance component.

6. The method of claim 5, wherein the fault-detection impedance component comprises a reactive impedance portion.

7. The method of claim 5, wherein the fault-detection impedance component includes an inductor, and wherein a core of the inductor comprises a ferrite core, a ferromagnetic core, and/or an air core.

8. The method of claim 4, wherein the reference impedance is between 5% and 90% of the impedance along the path, between 5%, and 80% of the impedance along the path, between 5% and 70% of the impedance along the path, between 5% and 60% of the impedance along the path, between 5% and 50% of the impedance along the path, between 5% and 40% of the impedance along the path, between 5% and 30% of the impedance along the path, between 5% and 20% of the impedance along the path, between 5% and 10% of the impedance along the path, less than or equal to 10% of the impedance along the path, less than or equal to 5% of the impedance along the path, or less than or equal to 1% of the impedance along the path.

9. The method of claim 1, further comprising determining the measured impedance between the conductor and the ground node.

10. The method of claim 9, wherein determining the measured impedance between the conductor and the ground node comprises determining an impedance between two nodes along an electrical path between the conductor and the ground node.

11. The method claim 1, wherein mitigating the ground fault comprises presenting a message relating to the fault.

12. The method of claim 1, wherein mitigating the ground fault comprises signaling an inverter of the photovoltaic system to cease commutation and/or to open protection disconnects.

13. The method of claim 1, wherein mitigating the ground fault comprises deactivating one or more photovoltaic cells.

14. A device configured to couple one or more photovoltaic cells to an inverter, the device comprising:
a terminal configured to couple one or more photovoltaic cells to an inverter via a conductor, the conductor being coupled to a ground node by a fuse circuit; and
a fault-detection impedance component coupled to the conductor in series with the fuse circuit.

15. The device of claim 14, wherein the fault-detection impedance component is coupled between the fuse circuit and the terminal, or between the fuse circuit and the ground node.

16. The device of claim 14, wherein the fault-detection impedance component comprises an inductor.

17. The device of claim 16, wherein the inductor comprises a ferrite core, a ferromagnetic core, and/or an air core.

18. The device of claim 14, further comprising one or more components configured to measure an impedance between the conductor and the ground node.

19. A photovoltaic system comprising:
an inverter;
one or more photovoltaic cells coupled to the inverter via a conductor, the conductor being coupled to a ground node of the photovoltaic system by a fuse circuit; and
a fault-detection impedance component coupled to the conductor and in series with the fuse circuit.

20. The photovoltaic system of claim 19, wherein the fault-detection impedance component comprises an inductor.
